(19) United States
(12) Patent Application Publication
(10) Pub. No.: US 2025/0063677 A1
(43) Pub. Date: Feb. 20, 2025

(54) FLEXIBLE DISPLAY MODULE AND FLEXIBLE DISPLAY DEVICE

(71) Applicants: WUHAN CHINA STAR OPTOELECTRONICS TECHNOLOGY CO., LTD., Wuhan, Hubei (CN); WUHAN CHINA STAR OPTOELECTRONICS SEMICONDUCTOR DISPLAY TECHNOLOGY CO., LTD., Wuhan, Hubei (CN)

(72) Inventor: Yali LIU, Wuhan, Hubei (CN)

(21) Appl. No.: 17/593,915

(22) PCT Filed: Jul. 22, 2021
(86) PCT No.: PCT/CN2021/107824

§ 371 Date: Nov. 13, 2024

(30) Foreign Application Priority Data
Jun. 23, 2021 (CN) 202110697495.8

(51) Int. Cl. H05K 5/03

(52) U.S. Cl. CPC H05K 5/03

(57) ABSTRACT

A flexible display module and a flexible display device are provided. The flexible display module includes a bending region and non-bending regions located on two sides of the bent region, and includes a display panel and a cover window located on a light emitting side of the display panel, where at least one first groove is disposed on a side surface of the cover window corresponding to the bending region away from the display panel, a filling layer is disposed in the first groove, and reflectivity of the filling layer is less than reflectivity of the cover window.

### FIELD OF DISCLOSURE

The present disclosure relates to the field of display technologies, and more particularly to a flexible display module and a flexible display device.

### BACKGROUND OF RELATED ARTS

A flexible display technology is an important trend of development of a current active-matrix organic light emitting diode (AMOLED) display panel. Currently, foldable flexible display panels have gone into mass production in succession, and all of whole machines can be bent for more than 200,000 times. However, after being bent for a plurality of times or being placed for a long time, irreversible folds are generated on surfaces of bent regions of the flexible display panels, thereby affecting the visual effect. Therefore, how to eliminate the folds in the bent regions of the flexible display panels becomes a research objective in the display industry. A fold is imaging perception of human eyes for creases in a bending region of a flexible display panel, and in this industry, the fold problem of the bent region of the flexible display panel has been alleviated from aspects such as thinning an overall stacking structure and a whole machine shape design of the flexible display panel.

In a conventional flexible display module, functional layers such as a polarizer and a cover window are usually disposed on the display panel. The cover window protects the display panel and improves certain surface hardness. In the related art, a material of ultra thin glass (UTG) is used for manufacturing the cover window to alleviate folds in a bending region and alleviate scraping conditions, but thinner UTG with an integral surface has a limited alleviation on human eyes imaging in folds, and folds imaged in a bright region are also generated in the bending region of the flexible display module, thereby affecting the visual effect. Therefore, it is necessary to alleviate this defect.

### SUMMARY OF INVENTION

### Technical Problems

This application provides a flexible display module, configured to resolve a technical problem of the low visual effect caused by folds in a bending region of the flexible display module in the related art.

### Solution to Problem

### Technical Solutions

An embodiment of this application provides a flexible display module, comprising a bending region and non-bending regions located on two sides of the bent region, and comprising a display panel and a cover window located on a light emitting side of the display panel, where at least one first groove is disposed on a side surface of the cover window corresponding to the bending region away from the display panel, a filling layer is disposed in the first groove, and reflectivity of the filling layer is less than reflectivity of the cover window.

In the flexible display module provided in this embodiment of this application, a material of the cover window is UTG.

In the flexible display module provided in this embodiment of this application, a material of the filling layer is tetraalkoxysilane, or a compound having a fluoroalkyl structure and a polysiloxane structure.

In the flexible display module provided in this embodiment of this application, a depth of the first groove is greater than ½ of a thickness of the cover window of the non-bending region, and is less than the thickness of the cover window of the non-bending region.

In the flexible display module provided in this embodiment of this application, the thickness of the cover window of the non-bending region is greater than or equal to 60 μm, and is less than or equal to 100 μm.

In the flexible display module provided in this embodiment of this application, a shape of a longitudinal section of the first groove is one of a rectangle, a semicircle, a half-elliptical shape, or a half-rounded rectangle.

In the flexible display module provided in this embodiment of this application, an orthographic projection of the first groove on the display panel covers the bending region.

In the flexible display module provided in this embodiment of this application, at least one second groove is disposed on a side surface of the cover window corresponding to the bending region close to the display panel, and the filling layer is disposed in the second groove.

In the flexible display module provided in this embodiment of this application, a sum of the depth of the first groove and a depth of the second groove is greater than ½ of the thickness of the cover window of the non-bending region, and is less than the thickness of the cover window of the non-bending region.

In the flexible display module provided in this embodiment of this application, a shape of a longitudinal section of the second groove is the same as the shape of the longitudinal section of the first groove.

An embodiment of this application further provides a flexible display device, comprising a drive chip and a flexible display module, the flexible display module comprising a bending region and non-bending regions located on two sides of the bent region, and further comprising a display panel and a cover window located on a light emitting side of the display panel, where at least one first groove is disposed on a side surface of the cover window corresponding to the bending region away from the display panel, a filling layer is disposed in the first groove, and reflectivity of the filling layer is less than reflectivity of the cover window.

In the flexible display device provided in this embodiment of this application, a material of the cover window is UTG.

In the flexible display device provided in this embodiment of this application, a material of the filling layer is tetraalkoxysilane, or a compound having a fluoroalkyl structure and a polysiloxane structure.

In the flexible display device provided in this embodiment of this application, a depth of the first groove is greater than ½ of a thickness of the cover window of the non-bending region, and is less than the thickness of the cover window of the non-bending region.

In the flexible display device provided in this embodiment of this application, the thickness of the cover window of the non-bending region is greater than or equal to 60 μm, and is less than or equal to 100 μm.

In the flexible display device provided in this embodiment of this application, a shape of a longitudinal section of the first groove is one of a rectangle, a semicircle, a half-elliptical shape, or a half-rounded rectangle.

In the flexible display device provided in this embodiment of this application, an orthographic projection of the first groove on the display panel covers the bending region.

In the flexible display device provided in this embodiment of this application, at least one second groove is disposed on a side surface of the cover window corresponding to the bending region close to the display panel, and the filling layer is disposed in the second groove.

In the flexible display device provided in this embodiment of this application, a sum of the depth of the first groove and a depth of the second groove is greater than ½ of the thickness of the cover window of the non-bending region, and is less than the thickness of the cover window of the non-bending region.

In the flexible display device provided in this embodiment of this application, a shape of a longitudinal section of the second groove is the same as the shape of the longitudinal section of the first groove.

### Advantages of Invention

### Beneficial Effects

This application provides a flexible display module, comprising a bending region and non-bending regions located on two sides of the bending region, and comprising a display panel and a cover window located on a light emitting side of the display panel, where at least one first groove is disposed on a side surface of the cover window corresponding to the bending region away from the display panel, a filling layer is disposed in the first groove, and reflectivity of the filling layer is less than reflectivity of the cover window. In this embodiment of this application, the at least one first groove is disposed on the side surface of the cover window of the bending region away from the display panel, the filling layer is disposed in the first groove, and the reflectivity of the filling layer is less than the reflectivity of the cover window, thereby reducing reflectivity of the bending region, reducing human eyes imaging in folds in the bending region, and improving the visual effect of the bending region.

### BRIEF DESCRIPTION OF DRAWINGS

### Description of Attached Drawings

FIG. 1 is a schematic diagram of a basic structure of a flexible display module according to an embodiment of this application;

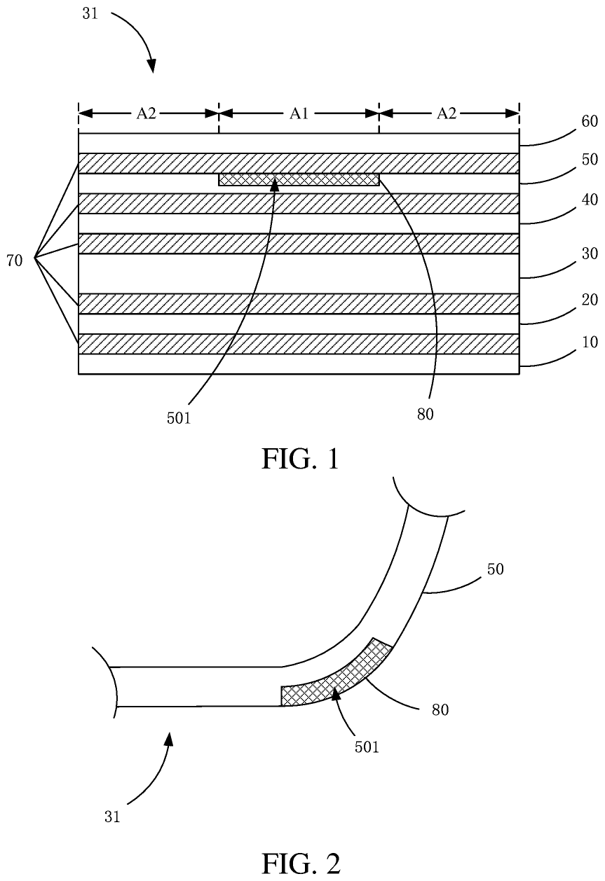

FIG. 2 is a longitudinal sectional view of a bent state of a cover window according to an embodiment of this application;

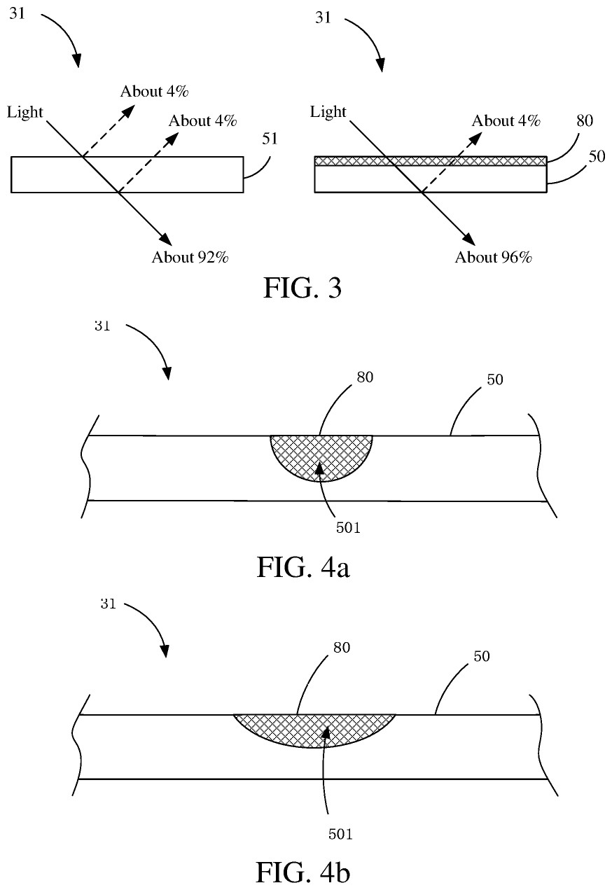

FIG. 3 is a comparison diagram of a cover window of a bent region according to an embodiment of this application and a cover window in the related art;

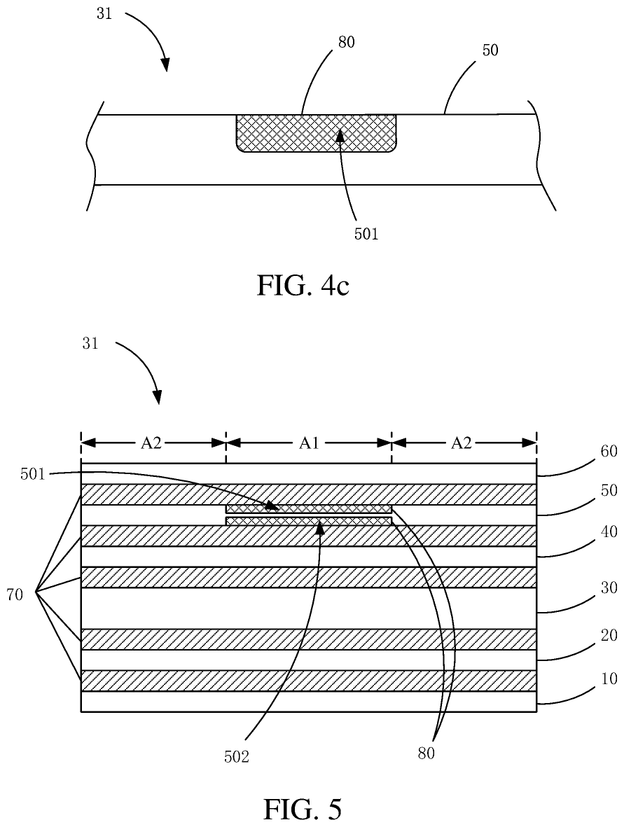

FIG. 4a to FIG. 4c are longitudinal sectional views of an unbent state of a cover window according to an embodiment of this application;

FIG. 5 is a schematic diagram of a basic structure of another flexible display module according to an embodiment of this application;

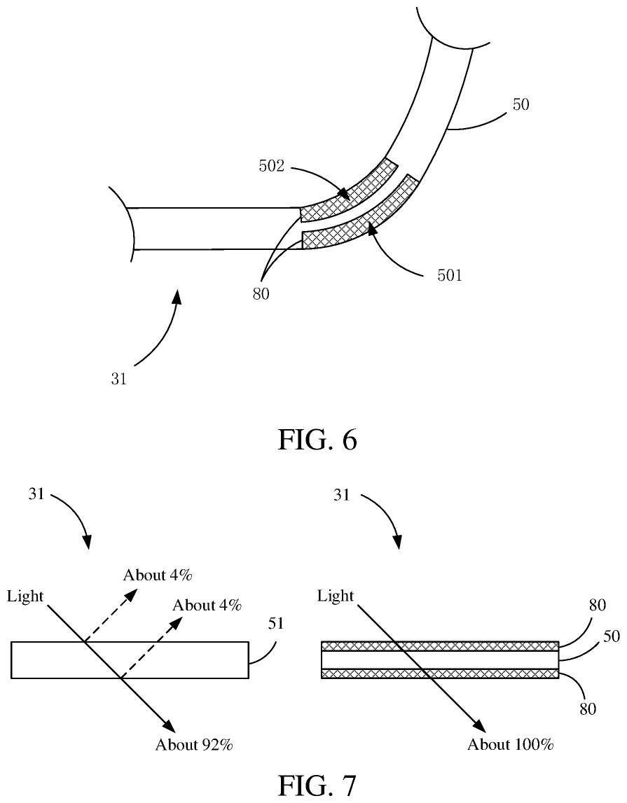

FIG. 6 is a longitudinal sectional view of a bent state of another cover window according to an embodiment of this application; and

FIG. 7 is a comparison diagram of another cover window of a bent region according to an embodiment of this application and a cover window in the related art.

### EMBODIMENTS OF INVENTION

### Detailed Description of Preferred Embodiments

To make objectives, technical solutions, and effects of this application clearer and more explicit, the following further describes this application in detail with reference to the accompanying drawings and embodiments. In the accompanying drawings, for clearance and case to understand and describe, a size and thickness of a component shown in the accompanying drawings are not drawn to scale.

FIG. 1 is a schematic diagram of a basic structure of a flexible display module according to an embodiment of this application. The flexible display module includes a bending region A1 and non-bending regions A2 located on two sides of the bending region A1, and includes a display panel 30 and a cover window 50 located on a light emitting side 31 of the display panel 30, where at least one first groove 501 is disposed on a side surface of the cover window 50 corresponding to the bending region A1 away from the display panel 30, a filling layer 80 is disposed in the first groove 501, and reflectivity of the filling layer 80 is less than reflectivity of the cover window 50.

It should be noted that, the light emitting side 31 of the display panel 30 refers to a side for human eyes to receive a message. The bendable display panel 30 is relatively soft and not scratch-resistant, so that the touch feeling of a user is not good enough. Therefore, one layer of the cover window 50 needs to be disposed on the light emitting side 31 of the display panel 30, to improve hardness and wear-resistance performance of the flexible display module. However, a cover window in the related art is attached using an integral layer, and has certain creases after being bent for a plurality of times, so that human eyes imaging in folds exists in the bent region A1, thereby causing the relatively poor visual effect. In this embodiment of this application, the at least one first groove 501 is disposed on the side surface of the cover window 50 of the bending region A1 away from the display panel 30, the filling layer 80 is disposed in the first groove 501, and the reflectivity of the filling layer 80 is less than the reflectivity of the cover window 50. That is, in this application, a low-reflectivity material (that is, an anti-reflection film layer) is disposed on one side of the cover window 50 close to the light emitting side 31, so that a large fraction of light incident on the light emitting side 31 of the flexible display module can be refracted, and a relatively small fraction of the light can be reflected. In this case, a relatively small fraction of the light is received by the human eyes, in other words, human eyes imaging in folds is reduced, thereby ensuring imaging quality of the bending region A1 and reducing the vertigo feeling, that is, the visual effect of the bending region A1 is improved.

In an embodiment, a material of the cover window 50 is UTG, and a material of the filling layer 80 is tetraalkoxysilane, or a compound having a fluoroalkyl structure and a polysiloxane structure. It may be understood that, the UTG is a bendable material, not only having certain hardness, but also having performance of anti-scraping and wear-resistance. The UTG not only can improve surface hardness of the flexible display module, but also can protect the display panel 30 under the UTG. A molecular formula of tetraalkoxysilane is Si(OR)₄, where R represents a methyl or an ethyl.

In an embodiment, a method for preparing the flexible display module includes the following steps: providing a display panel 30; preparing one layer of cover window 50 on a light emitting side 31 of the display panel 30; preparing at least one first groove 501 on a side surface of the cover window 50 corresponding to the bending region A1 away from the display panel 30; and preparing a filling layer 80 in the first groove 501. Reflectivity of the filling layer 80 is less than reflectivity of the cover window 50.

It should be noted that, the first groove 501 is prepared using an etching cutting process. In an embodiment, a depth of the first groove 501 is greater than ½ of a thickness of the cover window 50 of the non-bending region A2, and is less than the thickness of the cover window 50 of the non-bending region A2. Specifically, the thickness of the cover window 50 of the non-bending region A2 is greater than or equal to 60 μm, and is less than or equal to 100 μm.

In an embodiment, the depth of the first groove 501 is greater than or equal to 30 μm, and is less than or equal to 70 μm. After the first groove 501 is formed, a thickness of a remaining cover window 50 (that is, a cover window 50 located under the first groove 501) is within 30 μm, that is, greater than 0 and less than or equal to 30 μm.

In this embodiment, a shape of a longitudinal section of the first groove 501 is a rectangle. In other embodiments, the shape of the longitudinal section of the first groove 501 can alternatively be one of a semicircle, a half-elliptical shape, or a half-rounded rectangle. It should be noted that, the longitudinal section refers to a plane perpendicular to a plane in which the cover window 50 is located.

In this embodiment, there is one first groove 501, and an orthographic projection of the first groove 501 on the display panel 30 covers the bending region A1. It can be understood that, a cross-sectional area of the first groove 501 is greater than or equal to a cross-sectional area of the bending region A1 (a cross-section refers to a plane parallel to the plane in which the cover window 50 is located), in other words, a region including the filling layer 80 can completely cover the bending region A1. Therefore, the reflectivity of the entire bending region A1 can be reduced, and the display effect of the entire bending region A1 can be improved. In other embodiments, there are a plurality of first grooves 501, in other words, the reflectivity of the bending region A1 can alternatively be partially improved, so as to improve the display effect of the bending region A1.

In an embodiment, the flexible display module further includes a support layer 10, a barrier layer 20 located above the support layer 10, a polarizer 40 located above the display panel 30, and a protective layer 60 located above the cover window 50, where optically clear adhesive layers 70 are used for adhesively fixing the support layer 10 to the barrier layer 20, the barrier layer 20 to the display panel 30, the display panel 30 to the polarizer 40, the polarizer 40 to the cover window 50, and the cover window 50 to the protective layer 60. Specifically, a material of the support layer 10 can be a steel sheet, and materials of the barrier layer 20 and the protective layer 60 can be a polyimide film.

Next, FIG. 2 is a longitudinal sectional view of a bent state of a cover window according to an embodiment of this application. According to a bent direction of the cover window 50 provided in this embodiment of this application, two sides of the cover window 50 are bent from a plane in which the light emitting side 31 of the flexible display module is located to a side away from the light emitting side 31. Therefore, the first groove 501 is disposed at a bent bulge portion. In this embodiment of this application, the first groove 501 is disposed in the bending region, and the filling layer 80 is disposed in the first groove 501, so as to reduce the reflectivity of the bending region, and further relieve a bending stress of the bending region.

Next, FIG. 3 is a comparison diagram of a cover window of a bending region according to an embodiment of this application and a cover window in the related art, where a figure at a left side represents a cover window 51 in the related art. As can be vividly seen from the figure, when light incident on the cover window 51 is incident on a first surface of the cover window 51, about 4% of the light is reflected, and when the light is incident on a second surface of the cover window 51, about 4% of the light is reflected. Therefore, about 92% of the incident light remains. A figure at a right side of FIG. 3 represents the cover window 50 of the bending region provided in this embodiment of this application. As can be vividly seen from the figure, when light incident on the cover window 50 is incident on a first surface of the cover window 50, almost no light is reflected, and when the light is incident on a second surface of the cover window 50, about 4% of the light is reflected. Therefore, about 96% of the incident light remains. It can be known from the above comparison that, in this embodiment of this application, the filling layer 80 is disposed on a side surface of the cover window 50 of the bending region close to the light emitting side 31, and the reflectivity of the filling layer 80 is less than the reflectivity of the cover window 50, so as to reduce reflectivity of the first surface of the cover window 50 and reduce human eyes imaging in folds in the bending region, thereby improving the display effect.

In addition, FIG. 4a to FIG. 4c are longitudinal sectional views of an unbent state of a cover window according to an embodiment of this application. At least one first groove 501 is disposed on the side surface of the cover window 50 close to the light emitting side 31, the filling layer 80 is disposed in the first groove 501, and the reflectivity of the filling layer 80 is less than the reflectivity of the cover window 50. The shape of the longitudinal section of the first groove 501can be a semicircle (as shown in FIG. 4a), a half-elliptical shape (as shown in FIG. 4b), or a half-rounded rectangle (as shown in FIG. 4c), so as to facilitate etching processing.

It should be noted that, the first groove 501 is prepared by using the etching cutting process. In an embodiment, the depth of the first groove 501 is greater than or equal to 30 μm, and is less than or equal to 70 μm. After the first groove 501 is formed, a thickness of a remaining cover window 50 (that is, a cover window 50 located under the first groove 501) is within 30 μm, that is, greater than 0 and less than or equal to 30 μm.

Further, FIG. 5 is a schematic diagram of a basic structure of another flexible display module according to an embodiment of this application. The flexible display module includes a bending region A1 and non-bending regions A2 located on two sides of the bending region A1, and includes a display panel 30 and a cover window 50 located on a light emitting side 31 of the display panel 30, where at least one first groove 501 is disposed on a side surface of the cover window 50 corresponding to the bending region A1 away from the display panel 30, a filling layer 80 is disposed in the first groove 501, and reflectivity of the filling layer 80 is less than reflectivity of the cover window 50.

In this embodiment, at least one second groove 502 is disposed on a side surface of the cover window 50 corresponding to the bending region A1 close to the display panel 30, and the filling layer 80 is disposed in the second groove 502. It may be understood that, a difference between the flexible display module in this embodiment and the flexible display module in FIG. 1 is that, in this embodiment, the filling layer 80 is also disposed on the side surface of the cover window 50 close to the display panel 30. In this embodiment, a low-reflectivity material (that is, an anti-reflection film layer) is disposed on both surfaces of the cover window 50, so as to further reduce the reflectivity of the bending region A1 and further reduce human eyes imaging in folds in the bending region A1, thereby further improving the display effect of the bending region A1.

In an embodiment, a sum of a depth of the first groove 501 and a depth of the second groove 502 is greater than ½ of a thickness of the cover window 50 of the non-bending region A2, and is less than the thickness of the cover window 50 of the non-bending region A2. Specifically, the thickness of the cover window 50 of the non-bending region A2 is greater than or equal to 60 μm, and is less than or equal to 100 μm.

In an embodiment, the sum of the depth of the first groove 501 and the depth of the second groove 502 is greater than or equal to 30 μm, and is less than or equal to 70 μm. A distance between the bottom of the first groove 501 and the bottom of the second groove 502 is within 30 μm, that is, greater than 0 and less than or equal to 30 μm.

In this embodiment, longitudinal sections of the first groove 501 and the second groove 502 are both in the shape of a rectangle. In other embodiments, the longitudinal sections of the first groove 501 and the second groove 502 can be also in the shape of one of a semicircle, a half-elliptical shape, or a half-rounded rectangle. In an embodiment, the shape of the longitudinal section of the second groove 502 is the same as the shape of the longitudinal section of the first groove 501.

In this embodiment, there are one first groove 501 and one second groove 502, and orthographic projections of the first groove 501 and the second groove 502 on the display panel 30 cover the bending region A1. It may be understood that, cross-sectional areas of the first groove 501 and the second groove 502 are greater than or equal to a cross-sectional area of the bending region A1, in other words, a region including the filling layer 80 can completely cover the bending region A1. Therefore, the reflectivity of the entire bending region A1 can be reduced, and the display effect of the entire bending region A1 can be improved. In other embodiments, there can be a plurality of first grooves 501 and a plurality of second grooves 502.

In an embodiment, the orthographic projection of the first groove 501 on the display panel 30 is not overlapped with the orthographic projection of the second groove 502 on the display panel 30. Specifically, the orthographic projection of the first groove 501 on the display panel 30 is complementary with the orthographic projection of the second groove 502 on the display panel 30.

Next, FIG. 6 is a longitudinal sectional view of a bent state of another cover window according to an embodiment of this application. According to a bent direction of the cover window 50 provided in this embodiment of this application, two sides of the cover window 50 are bent from a plane in which the light emitting side 31 of the flexible display module is located to a side away from the light emitting side 31. Therefore, the first groove 501 is disposed at a bent bulge portion, and the second groove 502 is disposed at a bent recessed portion. In this embodiment of this application, the first groove 501 and the second groove 502 are disposed in the bending region, and the filling layer 80 is disposed in the first groove 501 and the second groove 502, so as to reduce the reflectivity of the bending region, and further relieve a bending stress of the bending region.

Furthermore, FIG. 7 is a comparison diagram of another cover window of a bending region according to an embodiment of this application and a cover window in the related art, where a figure at a left side represents a cover window 51 in the related art. As can be vividly seen from the figure, when light incident on the cover window 51 is incident on a first surface of the cover window 51, about 4% of the light is reflected, and when the light is incident on a second surface of the cover window 51, about 4% of the light is reflected. Therefore, about 92% of the incident light remains. A figure at a right side of FIG. 7 represents the cover window 50 of the bending region provided in this embodiment of this application. As can be vividly seen from the figure, when light incident on the cover window 50 is incident on a first surface of the cover window 50, almost no light is reflected, and when the light is incident on a second surface of the cover window 50, almost no light is reflected, too. Therefore, about 100% of the incident light passes through the cover window 50. It can be known from the above comparison that, in this embodiment of this application, the filling layer 80 is disposed on a side surface of the cover window 50 of the bending region close to the light emitting side 31 and a side surface of the cover window 50 of the bending region away from the light emitting side 31, and the reflectivity of the filling layer 80 is less than the reflectivity of the cover window 50, so as to reduce reflectivity of the first surface and the second surface of the cover window 50, and further reduce human eyes imaging in folds in the bending region, thereby improving the display effect.

An embodiment of this application further provides a flexible display device, including a drive chip and the foregoing flexible display module. A structure of the flexible display module can refer to FIG. 1 to FIG. 7 and related descriptions. The flexible display device provided in this embodiment of this application can be a product or a component having a display function, such as a mobile phone, a tablet computer, a laptop computer, a digital camera, and a navigator.

In conclusion, the embodiments of this application provide a flexible display module, including a bending region and non-bending regions located on two sides of the bending region, and including a display panel and a cover window located on a light emitting side of the display panel, where at least one first groove is disposed on a side surface of the cover window corresponding to the bending region away from the display panel, a filling layer is disposed in the first groove, and reflectivity of the filling layer is less than reflectivity of the cover window. In this embodiment of this application, the at least one first groove is disposed on the side surface of the cover window of the bending region away from the display panel, the filling layer is disposed in the first groove, and the reflectivity of the filling layer is less than the reflectivity of the cover window, to reduce reflectivity of the bending region and human eyes imaging in folds in the bending region, thereby improving the visual effect of the bending region. In this case, a technical problem of the low visual effect caused by folds in the bending region of the flexible display module in the related art is resolved.

In the foregoing embodiments, description of each embodiment focuses on a different part, and for parts not described in detail in one embodiment, reference may be made to the related description of other embodiments.

It may be understood that, any equivalent modification or replacement made by a person of ordinary skill in the art according to the technical solution and the inventive concept of this application shall fall within the protection scope of the appended claims of this application.

What is claimed is:

1. A flexible display module, comprising a bending region and non-bending regions located on two sides of the bending region, and comprising a display panel and a cover window located on a light emitting side of the display panel, wherein
at least one first groove is disposed on a side surface of the cover window corresponding to the bending region away from the display panel, a filling layer is disposed in the first groove, and reflectivity of the filling layer is less than reflectivity of the cover window.

2. The flexible display module according to claim 1, wherein a material of the cover window is ultra thin glass (UTG).

3. The flexible display module according to claim 2, wherein a material of the filling layer is tetraalkoxysilane, or a compound having a fluoroalkyl structure and a polysiloxane structure.

4. The flexible display module according to claim 1, wherein a depth of the first groove is greater than ½ of a thickness of the cover window of the non-bending region, and is less than the thickness of the cover window of the non-bending region.

5. The flexible display module according to claim 4, wherein the thickness of the cover window of the non-bending region is greater than or equal to 60 μm, and is less than or equal to 100 μm.

6. The flexible display module according to claim 1, wherein a shape of a longitudinal section of the first groove is one of a rectangle, a semicircle, a half-elliptical shape, or a half-rounded rectangle.

7. The flexible display module according to claim 1, wherein an orthographic projection of the first groove on the display panel covers the bending region.

8. The flexible display module according to claim 1, wherein at least one second groove is disposed on a side surface of the cover window corresponding to the bending region close to the display panel, and the filling layer is disposed in the second groove.

9. The flexible display module according to claim 8, wherein a sum of a depth of the first groove and a depth of the second groove is greater than ½ of a thickness of the cover window of the non-bending region, and is less than the thickness of the cover window of the non-bending region.

10. The flexible display module according to claim 8, wherein a shape of a longitudinal section of the second groove is the same as a shape of a longitudinal section of the first groove.

11. A flexible display device, comprising a drive chip and a flexible display module, the flexible display module comprising a bending region and non-bending regions located on two sides of the bending region, and further comprising a display panel and a cover window located on a light emitting side of the display panel, wherein
at least one first groove is disposed on a side surface of the cover window corresponding to the bending region away from the display panel, a filling layer is disposed in the first groove, and reflectivity of the filling layer is less than reflectivity of the cover window.

12. The flexible display device according to claim 11, wherein a material of the cover window is ultra thin glass (UTG).

13. The flexible display device according to claim 12, wherein a material of the filling layer is tetraalkoxysilane, or a compound having a fluoroalkyl structure and a polysiloxane structure.

14. The flexible display device according to claim 11, wherein a depth of the first groove is greater than ½ of a thickness of the cover window of the non-bending region, and is less than the thickness of the cover window of the non-bending region.

15. The flexible display device according to claim 14, wherein the thickness of the cover window of the non-bending region is greater than or equal to 60 μm, and is less than or equal to 100 μm.

16. The flexible display device according to claim 11, wherein a shape of a longitudinal section of the first groove is one of a rectangle, a semicircle, a half-elliptical shape, or a half-rounded rectangle.

17. The flexible display device according to claim 11, wherein an orthographic projection of the first groove on the display panel covers the bending region.

18. The flexible display device according to claim 11, wherein at least one second groove is disposed on a side surface of the cover window corresponding to the bending region close to the display panel, and the filling layer is disposed in the second groove.

19. The flexible display device according to claim 18, wherein a sum of a depth of the first groove and a depth of the second groove is greater than ½ of a thickness of the cover window of the non-bending region, and is less than the thickness of the cover window of the non-bending region.

20. The flexible display device according to claim 18, wherein a shape of a longitudinal section of the second groove is the same as a shape of a longitudinal section of the first groove.
